(19) United States
(12) Patent Application Publication
(10) Pub. No.: US 2019/0035930 A1
(43) Pub. Date: Jan. 31, 2019

(54) SEMICONDUCTOR STRUCTURE

(71) Applicant: MACRONIX INTERNATIONAL CO., LTD., Hsinchu (TW)

(72) Inventors: Yung-Hsiang Chen, Taipei City (TW); I-Chen Yang, Miaoli County (TW)

(21) Appl. No.: 15/664,010

(22) Filed: Jul. 31, 2017

(51) Int. Cl. H01L 29/78; H01L 29/08; H01L 21/266

(52) U.S. Cl. CPC H01L 29/7835; H01L 27/0922; H01L 21/266; H01L 29/0847

(57) ABSTRACT

A semiconductor structure includes a substrate, a first source/drain region, a second source/drain region, a channel doping region and a gate structure. The first source/drain region is disposed in the substrate. The first source/drain region includes a first region and a second region under the first region. The second source/drain region is disposed in the substrate. The second source/drain region is disposed opposite to the first source/drain region. The channel doping region is disposed in the substrate between the first source/drain region and the second source/drain region. The gate structure is disposed on the channel doping region. In a projection plane parallel to the top surface of the substrate, the second region of the first source/drain region is separated from the gate structure. The first source/drain region, the second source/drain region and the channel doping region have the same conductive type.

### TECHNICAL FIELD

This disclosure relates to a semiconductor structure, and more particularly to a semiconductor structure including a depletion-type MOSFET.

### BACKGROUND

Transistor is one of the most important types of electronic components in the modern electronic devices. The transistors may be used as amplifiers, switches, and/or the like. The metal-oxide-semiconductor field-effect transistor (MOSFET), among others, is the most widely used transistor now in both digital and analog circuits. Most of the MOSFETs are enhancement-type MOSFETs. Others are depletion-type MOSFETs. In an enhancement-type MOSFET, the conducting channel between the source and the drain is substantially not existed in general, and is formed by, for example, applying a voltage to the gate. In contrast, in a depletion-type MOSFET, the channel is previously formed by an ion implantation process, and the transistor is turned off by, for example, applying a voltage.

### SUMMARY

This disclosure is directed to a semiconductor structure, and more particularly to a semiconductor structure provided with a depletion-type MOSFET structure.

According to some embodiments, a semiconductor structure comprises a substrate, a first source/drain region, a second source/drain region, a channel doping region and a gate structure. The substrate has a top surface. The first source/drain region is disposed in the substrate. The first source/drain region comprises a first region and a second region under the first region. The second source/drain region is disposed in the substrate. The second source/drain region is disposed opposite to the first source/drain region. The channel doping region is disposed in the substrate between the first source/drain region and the second source/drain region. The gate structure is disposed on the substrate. The gate structure is disposed on the channel doping region. In a projection plane parallel to the top surface of the substrate, the second region of the first source/drain region is separated from the gate structure. The first source/drain region, the second source/drain region and the channel doping region have the same conductive type.

### BRIEF DESCRIPTION OF THE DRAWINGS

FIGS. 1A-1C illustrate an exemplary semiconductor structure according to embodiments and the formation thereof.

FIGS. 2A-2C illustrate an exemplary semiconductor structure according to embodiments and the formation thereof.

FIG. 3 illustrates an exemplary semiconductor structure according to embodiments.

FIG. 4 illustrates an exemplary semiconductor structure according to embodiments.

FIG. 5 illustrates a circuit arrangement for a semiconductor structure according to embodiments.

FIGS. 6A-6D illustrate structures and characteristics of an exemplary semiconductor structure according to embodiments and a comparative semiconductor structure thereof.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. Generally, only the differences with respect to individual embodiments are described. To facilitate understanding, identical reference numerals have been used, where possible, to designate identical elements that are common to the figures. In addition, for the clarity of the drawings, some reference numerals and/or elements may be omitted in some figures. The terms used to illustrate spatial relationships, such as “on”, “under”, “adjacent to”, or the like, may encompass both the conditions of directly contact and indirectly contact unless the term “directly” is used in the illustration. It is contemplated that elements and features of one embodiment may be beneficially incorporated into another embodiment without further recitation.

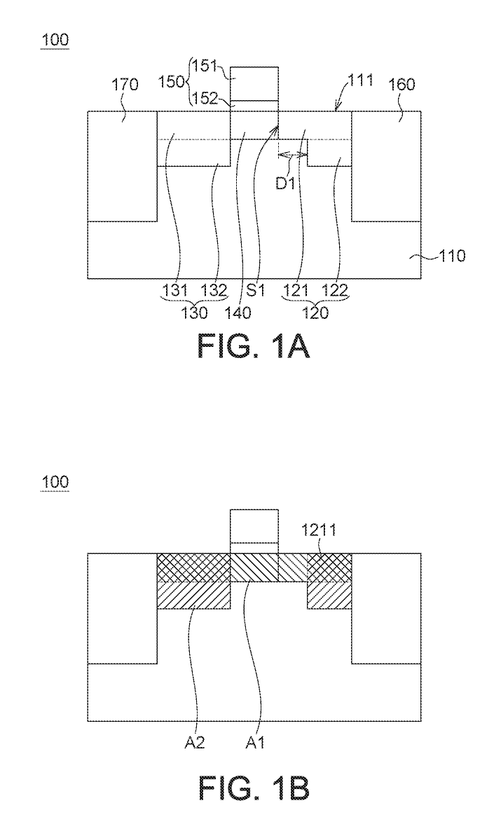

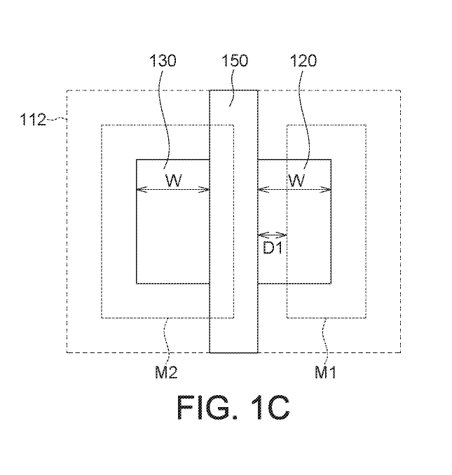

FIGS. 1A-1C illustrate an exemplary semiconductor structure according to embodiments and the formation thereof. As shown in FIG. 1A, the semiconductor structure 100 comprises a substrate 110, a first source/drain region 120, a second source/drain region 130, a channel doping region 140 and a gate structure 150. The substrate 110 has a top surface 111. The first source/drain region 120 is disposed in the substrate 110. The first source/drain region 120 comprises a first region 121 and a second region 122 under the first region 121. The second source/drain region 130 is disposed in the substrate 110. The second source/drain region 130 is disposed opposite to the first source/drain region 120. The channel doping region 140 is disposed in the substrate 110 between the first source/drain region 120 and the second source/drain region 130. The gate structure 150 is disposed on the substrate 110. More specifically, the gate structure 150 is disposed on the channel doping region 140. In a projection plane parallel to the top surface 111 of the substrate 110, such as the top surface 111 itself, the second region 122 of the first source/drain region 120 is separated from the gate structure 150. The first source/drain region 120, the second source/drain region 130 and the channel doping region 140 have the same conductive type.

Referring to FIGS. 1B and 1C, the first source/drain region 120, the second source/drain region 130 and the channel doping region 140 may be formed by ion implantation processes. The substrate 110 may comprise an intrinsic region 112, which is neither of n-type nor of p-type, and can be formed by intrinsic silicon. In some embodiments, the substrate 110 has a top surface with topography, and said top surface 111 is the flat top surface of a region of the substrate 110, and particularly the flat top surface of a region of the intrinsic region 112 of the substrate 110. The first source/drain region 120, the second source/drain region 130, the channel doping region 140 and the gate structure 150 may be formed in such an intrinsic region 112. The gate structure 150 may be firstly formed. Then, one or more suitable dopants can be implanted into the intrinsic region 112 to form the first source/drain region 120, the second source/drain region 130 and the channel doping region 140.

In some embodiments, the same conductive type of the first source/drain region 120, the second source/drain region 130 and the channel doping region 140 are n-type. In such a case, suitable dopants, such as arsenic (As) or the like, can be implanted into the intrinsic region 112 by two ion implantation processes for forming the first source/drain region 120, the second source/drain region 130 and the channel doping region 140 according to embodiments. In one ion implantation process, the dopant is implanted into the first implantation area A1, which is indicated by backslashes. In the other one ion implantation process, the dopant is implanted into the second implantation area A2, which is indicated by front slashes. The same dopant may be used in the two ion implantation processes. Alternatively, different dopants may be used. The doping concentrations may be the same in the two ion implantation processes. Alternatively, the doping concentrations are different while in the same order of magnitude. FIG. 1C shows mask-defined regions M1 and M2 for forming the second implantation area A2. According to some embodiments, mask-defined regions, such as the mask-defined regions M1 and M2, may be somewhat larger than the predetermined doping regions to provide a process window, as shown in FIG. 1C. The mask-defined region M1 corresponds to the first source/drain region 120. The mask-defined region M2 corresponds to the second source/drain region 130. In a projection plane as described above, as shown in FIG. 1C, the mask-defined region M1 is separated from the gate structure 150 by a distance D1. In some other embodiments, the same conductive type of the first source/drain region 120, the second source/drain region 130 and the channel doping region 140 are p-type. In some embodiments, the first source/drain region 120 is a drain region, and the second source/drain region 130 is a source region. In some other embodiments, the first source/drain region 120 is a source region, and the second source/drain region 130 is a drain region.

In the first source/drain region 120 formed by the two ion implantation processes as described above, due to the blocking effect of the gate structure 150, the first region 121 may have a side S1 aligned with the gate structure 150. The whole first region 121 experiences the ion implantation process corresponding to the first implantation area A1. A portion 1211 of the first region 121 further experiences the ion implantation process corresponding to the second implantation area A2. As such, at least the portion 1211 of the first region 121 has a total doping concentration higher than a doping concentration of the second region 122. The first source/drain region 120 and the second source/drain region 130 may have the same widths W. In said projection plane, the second region 122 of the first source/drain region 120, which experiences only the ion implantation process corresponding to the second implantation area A2, can be separated from the gate structure 150 by the distance D1 due to the definition of the mask-defined region M1. The distance D1 is smaller than the width W of the first source/drain region 120 or the second source/drain region 130. The second source/drain region 130 formed by the two ion implantation processes as described above comprises a first region 131 and a second region 132 under the first region 131. The first region 131 experiences both the ion implantation processes, while the second region 132 experiences only the ion implantation process corresponding to the second implantation area A2. As such, the first region 131 has a total doping concentration higher than a doping concentration of the second region 132. The channel doping region 140 experiences only the ion implantation process corresponding to the first implantation area A1.

The gate structure 150 may comprise a gate electrode 151 and a gate dielectric 152. The gate dielectric 152 is disposed under the gate electrode 151 for isolating the gate electrode 151 from the channel doping region 140.

The semiconductor structure 100 may further comprise a first isolation structure 160 and a second isolation structure 170. The first isolation structure 160 is disposed in the substrate 110. The second isolation structure 170 is disposed in the substrate 110. The second isolation structure 170 is disposed opposite to the first isolation structure 160. The first source/drain region 120, the second source/drain region 130 and the channel doping region 140 are disposed between the first isolation structure 160 and the second isolation structure 170. For example, the first isolation structure 160 and the second isolation structure 170 may be but not limited to shallow trench isolation structures.

The elements as described above may be used to constitute a transistor. More specifically, the semiconductor structure 100 may comprise a depletion-type MOSFET, which includes the first source/drain region 120, the second source/drain region 130, the channel doping region 140 and the gate structure 150. The depletion-type MOSFET may have a minus threshold voltage (V_{T}<0), which is provided by the channel doping region 140. Since no additional ion implantation processes is needed for forming such an improved depletion-type MOSFET, it can be formed with the same processes for other typical MOSFET comprising typical depletion-type MOSFETs and enhancement-type MOSFETs.

In some cases, due to the alignment deviation or other reasons in the ion implantation processes, the mask-defined region M2 designed for the second source/drain region 130 may be positioned across the gate structure 150. However, the embodiments described herein tolerate such cases.

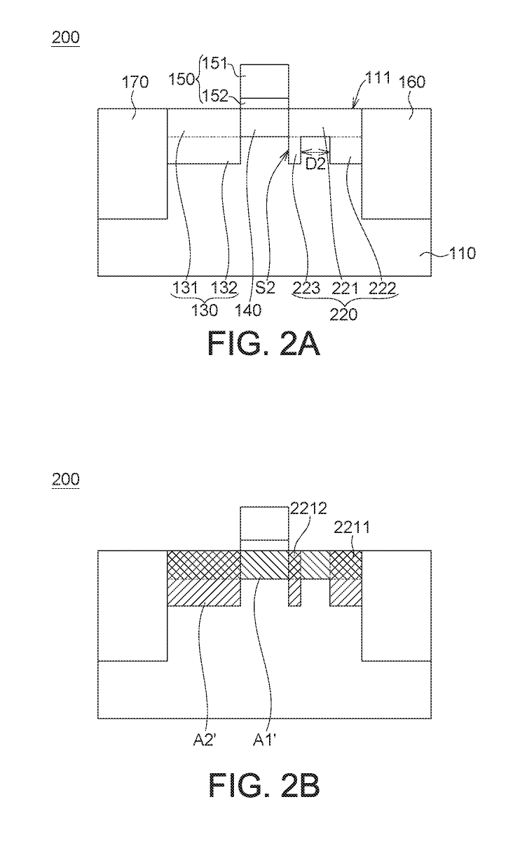

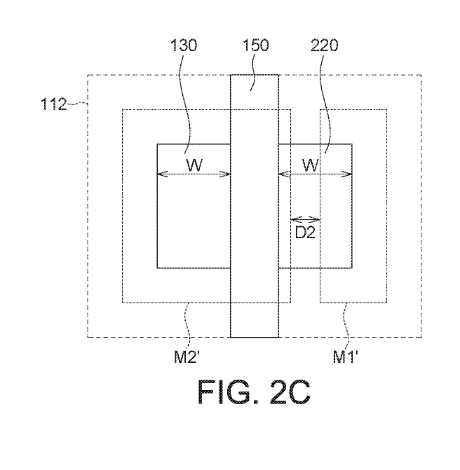

One such case, i.e., the semiconductor structure 200, is illustrated in FIGS. 2A-2C. As shown in FIG. 2C, the mask-defined region M2′ corresponding to the second source/drain region 130 is positioned across the gate structure 150. Thereby, as shown in FIGS. 2A and 2B, an additional third region 223 is formed in the first source/drain region 220 by the ion implantation process corresponding to the second implantation area A2′ with the mask-defined region M2′. As such, the first source/drain region 220 comprises a first region 221 and a second region 222, and further comprises a third region 223 under the first region 221. The third region 223 is separated from the second region 222, which is formed with the mask-defined region M1′. The third region 223 has a side S2 aligned with the gate structure 150. In the projection plane parallel to the top surface 111 of the substrate 110, the mask-defined region M1′ is separated from the mask-defined region M2′ by a distance D1. Thereby, the second region 222 can be separated from the third region 223 by the distance D1. The distance D1 is smaller than the width W of the first source/drain region 220 or the second source/drain region 130. In the first region 221 of the first source/drain region 220, a portion 2211 experiences the ion implantation process corresponding to the first implantation area A1′ and the ion implantation process corresponding to the second implantation area A2′ defined by the mask-defined region M1′, and a portion 2212 experiences the ion implantation process corresponding to the first implantation area A1′ and the ion implantation process corresponding to the second implantation area A2′ defined by the mask-defined region M2′. As such, at least the portions 2211 and 2212 of the first region 221 has a total doping concentration higher than a doping concentration of the second region 222 and a doping concentration of the third region 223. The doping concentration of the second region 222 can be the same as the doping concentration of the third region 223.

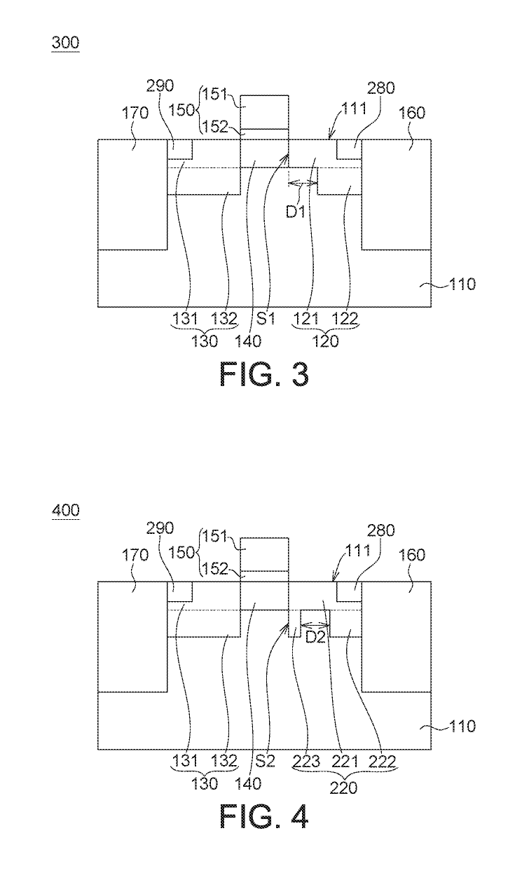

FIGS. 3 and 4 illustrate exemplary semiconductor structures 300 and 400, which are similar to the semiconductor structures 100 and 200, respectively, but further comprise a first source/drain contact 280 and a second source/drain contact 290. The first source/drain contact 280 is disposed in the first source/drain region 120/220. A doping concentration of the first source/drain contact 280 is higher than a doping concentration of the first source/drain region 120/220, such as in a different order of magnitude. The second source/drain contact 290 is disposed in the second source/drain region 130. A doping concentration of the second source/drain contact 290 is higher than a doping concentration of the second source/drain region 130, such as in a different order of magnitude. The first source/drain contact 280 and the second source/drain contact 290 have the same conductive type as the first source/drain region 120/220, the second source/drain region 130 and the channel doping region 140.

According to some embodiments, the semiconductor structure may be a memory structure, which has a cell region and a periphery region. The semiconductor structure may comprise a word line coupled to memory cells, such as NAND cells, disposed in the cell region. The semiconductor structure may further comprise a switch coupled to the word line, so as to control the signal transferred to the word line. In some embodiments, the switch is disposed in the cell region. A depletion-type MOSFET having the structure as described above may be used to form the switch.

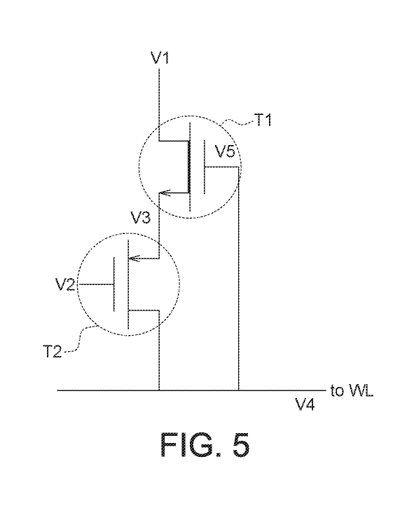

FIG. 5 shows a circuit arrangement of the semiconductor structure. The switch comprises two transistors T1 and T2. The transistor T1 may have a structure as illustrated with reference to any one of FIG. 1 to FIG. 4 or any other structure within the scope of the disclosure, wherein the conductive type of the first source/drain region 120/220, the second source/drain region 130 and the channel doping region 140 is n-type, the first source/drain region is a drain region, and the second source/drain region is a source region. In other words, the transistor T1 is a depletion-type NMOSFET according to the embodiments. The transistor T2 may be an enhancement-type PMOSFET.

For example, a program signal, such as a voltage V1 of 28V, may be provided and transferred to the drain of the transistor T1. It passes through the transistor T1, which is generally turned on. As such, a voltage V3 of 28V is transferred from the source of the transistor T1 to the transistor T2. When it is desired to provide the program signal to the word line (WL), the transistor T2 is turned on, such as by applying a voltage V2 of 0V to the gate thereof. As such, a voltage V4 of 28V (i.e., the program signal) can be provided to the word line. Due to the circuit design, the voltage signal is also transferred to the gate of the transistor T1. As such, a voltage V5 of 28V is applied to the gate of the transistor T1 and maintains the turn-on of the transistor T1. When it is not desired to provide the program signal to the word line, the transistor T2 is turned off, such as by applying a voltage V2 of 3.3V to the gate. As such, a voltage V4 of 0V is provided to the word line, and a voltage V5 of 0V is provided to the gate of the transistor T1. The zero voltage V5 will lead to the turn-off of the transistor T1, which may have a threshold voltage of −2.5V. When an equilibrium state is achieved, the voltage V3 may be about 3V.

For the transistor T1 in this circuit design, a large voltage difference exists between the gate and the drain when it is not desired to provide the program signal to the word line. As such, a higher breakdown voltage between the gate and the drain is preferred. In the example described above, the breakdown voltage should be larger than 28V, such as equal to or larger than about 30V. In contrast, such a large voltage difference does not exist between the gate and the source in both conditions. As such, a high breakdown voltage is not necessary between the gate and the source.

In the semiconductor structure according to the embodiments, due to the separation of the second region 122/222 from the gate structure 150, a total doping concentration nearby the gate structure 150 is decreased. The lower doping concentration in the drain side (120/220) where close to the gate structure 150 is beneficial for suppressing the gate-aided breakdown (i.e., increasing the gate-aided breakdown voltage). As such, a higher break down voltage can be obtained. In addition, since the second region 132 is not separated from the gate structure 150, the threshold voltage, which will be affected by the body effect at the source side, can be kept. This is advantageous for the transistor T1 used in the circuit design illustrated above, which should be generally turned-on.

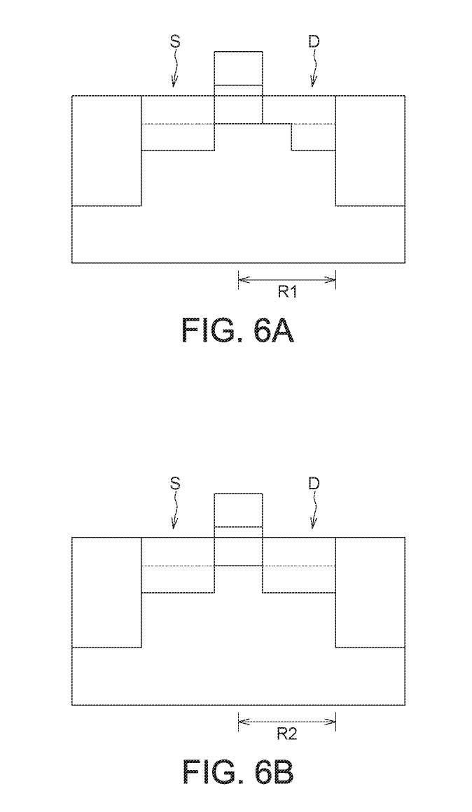

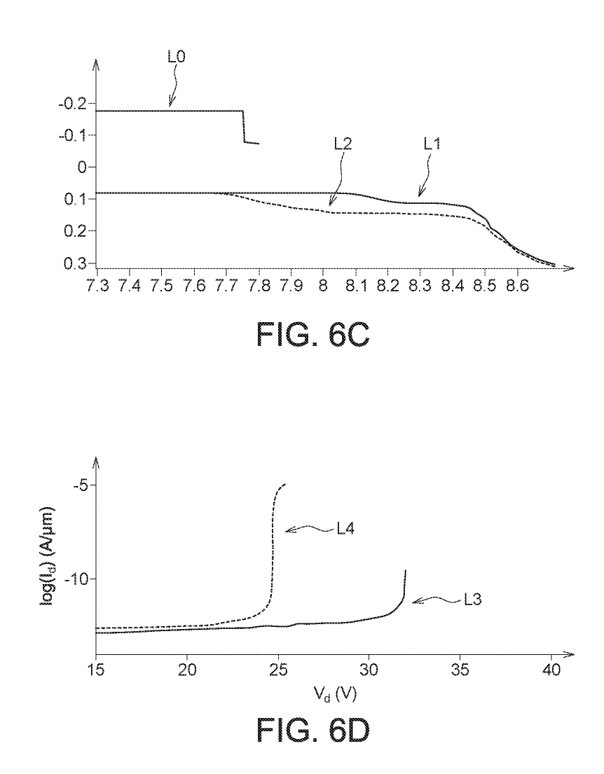

FIGS. 6A-6D illustrate structures and characteristics of an exemplary semiconductor structure according to embodiments and a comparative semiconductor structure thereof. FIG. 6A shows the asymmetric structure that is the same as the semiconductor structure 100, wherein the configuration at the drain side D is different from the configuration at the source side S. In this exemplary semiconductor structure, the distance D1 is 0.4 μm. FIG. 6B shows the comparative semiconductor structure, wherein the configuration at the drain side D is the same as the configuration at the source side S. FIG. 6C shows the simulation results of junction profiles corresponding to the regions R1 and R2 in FIGS. 6A and 6B, wherein the line L0 corresponds to the gate structure, the line L1 corresponds to the exemplary semiconductor structure, and the line L2 corresponds to the comparative semiconductor structure. It can be seen from FIG. 6C that the depth of the junction profile in the drain side D of the exemplary semiconductor structure is reduced compared to the comparative semiconductor structure, particularly in the region close to the gate structure. FIG. 6D shows the simulation results of I_{d}-V_{d} curves corresponding to FIGS. 6A and 6B, wherein the line L3 corresponds to the exemplary semiconductor structure, and the line L4 corresponds to the comparative semiconductor structure. It can be seen from FIG. 6D that the exemplary semiconductor structure has a higher breakdown voltage than the comparative semiconductor structure.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A semiconductor structure, comprising:
a substrate having a top surface;
a first source/drain region disposed in the substrate, the first source/drain region comprising a first region and a second region under the first region;
a second source/drain region disposed in the substrate, wherein the second source/drain region is disposed opposite to the first source/drain region;
a channel doping region disposed in the substrate between the first source/drain region and the second source/drain region; and
a gate structure disposed on the substrate, wherein the gate structure is disposed on the channel doping region;
wherein, in a projection plane parallel to the top surface of the substrate, the second region of the first source/drain region is separated from the gate structure;
wherein the first source/drain region, the second source/drain region and the channel doping region have the same conductive type; and
wherein at least a portion of the first region of the first source/drain region has a total doping concentration higher than a doping concentration of the second region of the first source/drain region.

2. The semiconductor structure according to claim 1, wherein the first region of the first source/drain region has a side aligned with the gate structure.

3. (canceled)

4. The semiconductor structure according to claim 1, wherein, in the projection plane parallel to the top surface of the substrate, the second region of the first source/drain region is separated from the gate structure by a distance smaller than a width of the first source/drain region or the second source/drain region.

5. The semiconductor structure according to claim 1, wherein the first source/drain region further comprises a third region under the first region, and the third region is separated from the second region.

6. The semiconductor structure according to claim 5, wherein the third region has a side aligned with the gate structure.

7. The semiconductor structure according to claim 5, wherein the total doping concentration is higher than a doping concentration of the third region.

8. The semiconductor structure according to claim 7, wherein the doping concentration of the second region is the same as the doping concentration of the third region.

9. The semiconductor structure according to claim 5, wherein, in the projection plane parallel to the top surface of the substrate, the second region is separated from the third region by a distance smaller than a width of the first source/drain region or the second source/drain region.

10. The semiconductor structure according to claim 1, wherein the second source/drain region comprising a first region and a second region under the first region of the second source/drain region, and the first region of the second source/drain region has a total doping concentration higher than a doping concentration of the second region of the second source/drain region.

11. The semiconductor structure according to claim 1, further comprising:
a first source/drain contact disposed in the first source/drain region, wherein a doping concentration of the first source/drain contact is higher than a doping concentration of the first source/drain region; and
a second source/drain contact disposed in the second source/drain region, wherein a doping concentration of the second source/drain contact is higher than a doping concentration of the second source/drain region;
wherein the first source/drain contact and the second source/drain contact have the same conductive type as the first source/drain region, the second source/drain region and the channel doping region.

12. The semiconductor structure according to claim 1, further comprising:
a first isolation structure disposed in the substrate; and
a second isolation structure disposed in the substrate, wherein the second isolation structure is disposed opposite to the first isolation structure;
wherein the first source/drain region, the second source/drain region and the channel doping region are disposed between the first isolation structure and the second isolation structure.

13. The semiconductor structure according to claim 1, wherein the same conductive type of the first source/drain region, the second source/drain region and the channel doping region are n-type.

14. The semiconductor structure according to claim 1, wherein the same conductive type of the first source/drain region, the second source/drain region and the channel doping region are p-type.

15. The semiconductor structure according to claim 1, wherein the first source/drain region is a drain region, and the second source/drain region is a source region.

16. The semiconductor structure according to claim 1, wherein the first source/drain region is a source region, and the second source/drain region is a drain region.

17. The semiconductor structure according to claim 1, comprising a depletion-type MOSFET including the first source/drain region, the second source/drain region, the channel doping region and the gate structure.

18. The semiconductor structure according to claim 17, wherein the depletion-type MOSFET has a minus threshold voltage.

19. The semiconductor structure according to claim 17, having a cell region and a periphery region, wherein the semiconductor structure comprises:
a word line coupled to memory cells that are disposed in the cell region; and
a switch coupled to the word line, the switch comprising the depletion-type MOSFET.

20. The semiconductor structure according to claim 19, wherein the switch is disposed in the cell region.
